(19) United States
(12) Patent Application Publication
(10) Pub. No.: US 2026/0050048 A1
(43) Pub. Date: Feb. 19, 2026

(54) MAGENTIC FIELD SENSOR WITH INDEPENDENT MAGNETIC FEEDBACK LOOPS

(71) Applicant: Allegro MicroSystems, LLC, Manchester, NH (US)

(72) Inventor: Conrado Rossi, Montevideo (UY)

(73) Assignee: Allegro MicroSystems, LLC, Manchester, NH (US)

(21) Appl. No.: 18/804,159

(22) Filed: Aug. 14, 2024

(51) Int. Cl. G01R 33/00; G01R 19/00; G01R 33/09

(52) U.S. Cl. CPC G01R 33/0041; G01R 19/0092; G01R 33/091; G01R 33/098

(57) ABSTRACT

A sensor, comprising: a first sensing bridge that is configured to generate, at least in part, a first sensing signal, the first sensing bridge including a plurality of first magnetic field sensing elements; a first amplifier that is configured to amplify the first sensing signal to generate a first amplified sensing signal; a first coil that is configured to receive the first amplified sensing signal and generate a feedback magnetic field in response; a second sensing bridge that is configured to generate, at least in part, a second sensing signal, the second sensing bridge including a plurality of second magnetic field sensing elements; a second amplifier that is configured to amplify the second sensing signal to generate a second amplified sensing signal; a second coil that is configured to receive the second amplified sensing signal and generate a second feedback magnetic field in response.

### BACKGROUND

As is known, sensors are used to perform various functions in a variety of applications. Some sensors include one or more magnetic field sensing elements, such as a Hall effect element or a magnetoresistive element, to sense a magnetic field associated with proximity or motion of a target object, such as a conductive and/or ferromagnetic object in the form of a gear or ring magnet, or to sense a current, as examples. Sensor integrated circuits are widely used in automobile control systems and other safety-critical applications. There are a variety of specifications that set forth requirements related to permissible sensor quality levels, failure rates, and overall functional safety.

### SUMMARY

According to aspects of the disclosure, a sensor is provided, comprising: a substrate; a first sensing bridge that is formed on the substrate, the first sensing bridge being configured to generate, at least in part, a first sensing signal, the first sensing bridge including a plurality of first magnetic field sensing elements; a first amplifier that is formed on the substrate, the first amplifier being configured to amplify the first sensing signal to generate a first amplified sensing signal; a first coil that is formed on the substrate, the first coil being configured to receive the first amplified sensing signal and generate a feedback magnetic field in response; a second sensing bridge that is formed on the substrate, the second sensing bridge being configured to generate, at least in part, a second sensing signal, the second sensing bridge including a plurality of second magnetic field sensing elements; a second amplifier that is formed on the substrate, the second amplifier being configured to amplify the second sensing signal to generate a second amplified sensing signal; a second coil that is formed on the substrate, the second coil being configured to receive the second amplified sensing signal and generate a second feedback magnetic field in response, wherein the first sensing bridge and the second sensing bridge are configured to form a differential magnetometer, such that an output signal of the sensor is based on a difference between the first sensing signal and the second sensing signal, and wherein the second coil is formed in such a physical location on the substrate, so as to cause a magnetic coupling between the second coil and the second sensing bridge to be substantially the same as a magnetic coupling between the first sensing bridge and the first coil.

According to aspects of the disclosure, a sensor is provided, comprising: a first sensing bridge that is configured to generate, at least in part, a first sensing signal, the first sensing bridge including a plurality of first magnetic field sensing elements; a first amplifier that is configured to amplify the first sensing signal to generate a first amplified sensing signal; a first coil that is configured to receive the first amplified sensing signal and generate a feedback magnetic field in response; a second sensing bridge that is configured to generate, at least in part, a second sensing signal, the second sensing bridge including a plurality of second magnetic field sensing elements; a second amplifier that is configured to amplify the second sensing signal to generate a second amplified sensing signal; a second coil that is configured to receive the second amplified sensing signal and generate a second feedback magnetic field in response, wherein the first sensing bridge and the second sensing bridge are configured to form a differential magnetometer, such that an output signal of the sensor is based on a difference between the first sensing signal and the second sensing signal.

According to aspects of the disclosure, a sensor is provided, comprising: a first magnetic field sensing component configured to generate a first sensing signal, the first magnetic field sensing component including one or more first magnetic field sensing elements; a first amplifier configured to amplify the first sensing signal to generate a first amplified sensing signal; a first coil configured to receive the first amplified sensing signal and generate a feedback magnetic field in response; a second magnetic field sensing component configured to generate a second sensing signal, the second magnetic field sensing component including one or more second magnetic field sensing elements; a second amplifier configured to amplify the second sensing signal to generate a second amplified sensing signal; a second coil configured to receive the second amplified sensing signal and generate a second feedback magnetic field in response, wherein a magnetic coupling between the second coil and the second magnetic field sensing component corresponds to a magnetic coupling between the first magnetic field sensing component and the first coil.

### BRIEF DESCRIPTION OF THE DRAWINGS

The foregoing features may be more fully understood from the following description of the drawings in which:

FIG. 1 is a diagram of an example of a sensor, according to aspects of the disclosure;

FIG. 2 is a diagram of an example of a sensor, according to aspects of the disclosure;

FIG. 3 is a diagram of an example of a sensor, according to aspects of the disclosure;

FIG. 4 is a diagram of an example of a sensor, according to aspects of the disclosure;

FIG. 5 is a diagram of an example of a pair of magnetic field sensing components, according to aspects of the disclosure; and

FIG. 6 is a diagram of an example of a sensor, according to aspects of the disclosure.

### DETAILED DESCRIPTION

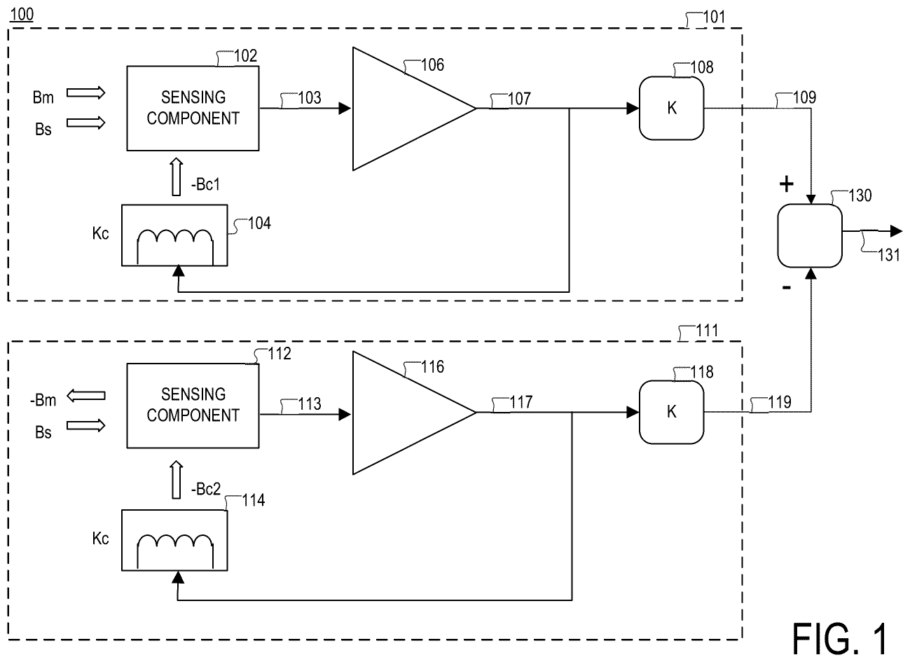

FIG. 1 is a schematic diagram of a sensor 100, according to one implementation. According to the present example, sensor 100 is a current sensor. However, it will be understood that the present disclosure is not limited to sensor 100 being any specific type of magnetic field sensor. By way of example, sensor 100 may be a position sensor, a torque sensor, a proximity sensor, an angle sensor, and/or any other suitable type of sensor.

Sensor 100 is implemented as a differential magnetometer in which each of the components has a dedicated magnetic feedback loop. Sensor 100 includes a portion 101, a portion 111, and a subtraction circuit 130. Each of portions 101 and 111 includes a respective magnetic field sensing component (e.g., see sensing components 102 and 112) and is provided a separate feedback coil, which is used to stabilize the portion's sensitivity and make it less susceptible to changes in sensitivity that are caused by aging and/or environmental factors, such as temperature, mechanical stress, stray magnetic fields, humidity, etc. The output of sensor 100 is generated, at least in part, by subtracting the output of portion 101 from the output of portion 111, or vice versa.

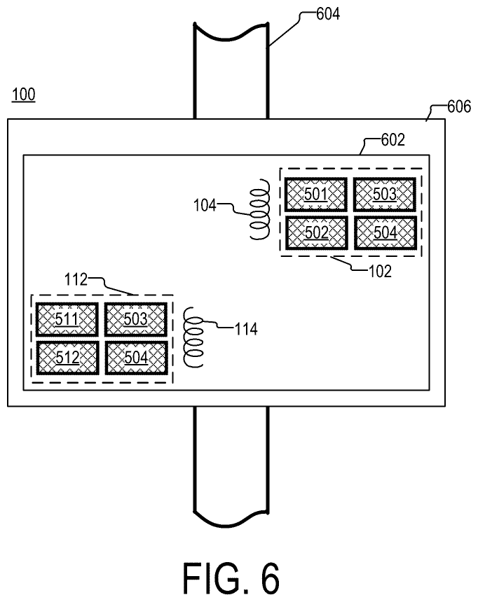

In the example of FIG. 1, each of the component outputs (which are subsequently subtracted) is generated by using a different feedback coil. This is advantageous as the magnetic field sensing components in each of portions 101 and 111 may be disposed in different parts of the sensor die (e.g., see substrate 602, shown in FIG. 6) and/or have different physical characteristics (e.g., due to manufacturing tolerances, etc.). In this regard, the provision of a separate feedback coil for each of the magnetic field sensing components allows finer control over the sensitivity of the magnetic field sensing components, which in turn results in an improved accuracy of sensor 100.

Portion 101 may include a sensing component 102, a feedback coil 104, an operational amplifier 106, and an element 108. Sensing component 102 may include one or more magnetic field sensing elements. By way of example, sensing component 102 may include a single sensing element. For instance, the sensing element may include a Hall element, a giant magnetoresistance (GMR) element, a tunneling magnetoresistance (TMR) element, and/or any other suitable type of magnetic field sensing element. As another example, sensing component 102 may include a bridge of magnetic field sensing elements. In some implementations, the bridge may be a half-bridge or a full-bridge circuit, such as a Wheatstone bridge. The feedback coil 104 may include a conductive trace or wire that is arranged to form one or more turns. The feedback coil 104 may be configured to generate a magnetic field Bc1.

Portion 111 may include a sensing component 112, a feedback coil 114, an operational amplifier 116, and an element 118. Sensing component 112 may include one or more magnetic field sensing elements. By way of example, sensing component 112 may include a single sensing element. For instance, the sensing element may include a Hall element, a giant magnetoresistance (GMR) element, a tunneling magnetoresistance (TMR) element, and/or any other suitable type of magnetic field sensing element. As another example, sensing component 112 may include a bridge of magnetic field sensing elements. In some implementations, the bridge may be a half-bridge or a full-bridge circuit, such as a Wheatstone bridge. The feedback coil 114 may include a conductive trace or wire that is arranged to form one or more turns. The feedback coil 114 may be configured to generate a magnetic field Bc2.

Sensing component 102 may be configured to sense magnetic fields Bm and Bs. Magnetic field Bm is a primary magnetic field, which is intentionally measured or monitored by sensor 100. According to the present example, magnetic field Bm is a magnetic field that is generated by a conductor (e.g., conductor 604, shown in FIG. 6) as a result of electrical current flowing through the conductor. However, in alternative implementations, magnetic field Bm may be a magnetic field that is generated, at least in part, by a magnetic target or another object, and which is desired to be measured by sensor 100. Magnetic field Bs is a stray magnetic field that interferes with the measurements of sensor 100. Magnetic field Bs can come from various sources, including nearby electrical devices or components, or other magnetic objects.

Sensing component 112 may also be configured to sense magnetic fields Bm and Bs. At the physical location of sensing component 102, magnetic field Bm may have a first direction, and, at the physical location of sensing component 112, magnetic field Bm may have a second direction. The second direction may be opposite to the first direction. Magnetic field Bs may have the same direction at the physical locations of both sensing components 102 and 112.

Sensing component 102 may generate a signal 103 in response to magnetic fields Bm and Bs. Amplifier 106 may amplify signal 103 to produce a signal 107. Signal 107 may be used to drive feedback coil 104. Furthermore, signal 107 may be provided to element 108. Element 108 may generate a signal 109 based on signal 107. Signal 109 may be provided to the subtraction circuit 130. Those of ordinary skill in the art will readily appreciate, after reading the present disclosure, that amplifier 106 may have a very large gain, as is often the case for closed-loop systems. By way of example, the gain of amplifier 106 may be in the range of 5000-10000 in some applications. However, the exact gain of amplifier 106 would depend on the particular application of sensor 100, and it can be determined without undue experimentation by those of ordinary skill in the art, after reading the present disclosure.

Sensing component 112 may generate a signal 113 in response to magnetic fields Bm and Bs. Amplifier 116 may amplify signal 113 to produce a signal 117. Signal 117 may be used to drive feedback coil 114. Furthermore, signal 117 may be provided to element 118. Element 118 may generate a signal 119 based on signal 117. Signal 119 may be provided to the subtraction circuit 130. Those of ordinary skill in the art will readily appreciate, after reading the present disclosure, that amplifier 116 may have a very large gain, as is often the case for closed-loop systems. By way of example, the gain of amplifier 116 may be in the range of 5000-10000 in some applications. However, the exact gain of amplifier 116 would depend on the particular application of sensor 100, and it can be determined without undue experimentation by those of ordinary skill in the art, after reading the present disclosure.

Subtraction circuit 130 may generate a signal 131 at least in part by subtracting signal 119 from signal 109. Signal 131 may be output to external circuitry that is coupled to sensor 100 or it may be passed to other components of sensor 100.

Feedback coil 104 may be configured to generate a magnetic field Bc1. Feedback coil 104 may be positioned in physical proximity to sensing component 102, such that magnetic field Bc1 is applied to sensing component 102. Magnetic field Bc1 may have a direction that is opposite to the direction of magnetic fields Bm and Bs at the physical location of sensing component 102. As noted above, the application of magnetic field Bc1 to sensing component 102 may help reduce fluctuations in the sensitivity of portion 101 that result from aging and/or environmental factors, such as temperature, mechanical stress, stray magnetic fields, or humidity, for example.

Feedback coil 114 may be configured to generate a magnetic field Bc2. Feedback coil 114 may be positioned in physical proximity to sensing component 112, such that magnetic field Bc2 is applied to sensing component 112. Magnetic field Bc2 may have a direction that is opposite to the direction of magnetic fields Bm and Bs at the physical location of sensing component 112. Magnetic field Bc2 may have a direction that is the same as the direction of magnetic Bm at the physical location of sensing component 112. As noted above, the application of magnetic field Bc2 to sensing component 112 may help reduce fluctuations in the sensitivity of portion 111 that result from aging and/or environmental factors, such as temperature, mechanical stress, stray magnetic fields, or humidity, for example.

FIG. 1 is schematic in nature, and it will be understood that the present disclosure is not limited to any specific implementation of sensor 100 for as long as each of the sensing components of sensor 100 is provided with a separate feedback coil that is driven with a signal produced by that sensing component. Although not shown in FIG. 1, sensor 100 may include additional circuitry. The additional circuitry may include any suitable type of digital or analog circuitry. By way of example, the additional circuitry may include a filter (digital or analog) one or more analog-to-digital converters (ADCs), one or more digital-to-analog converters (DACs) one or more filters (digital or analog), modulation and/or demodulation circuitry, one or more amplifiers, digital processing circuitry (such as a special-purpose processor and/or a CORDIC processor), and/or a communications interface, such as an I2C interface. The additional circuitry may be interposed between any two of the components that are shown in FIG. 1. Although, in the present example, amplifiers 106 and 116 have the same gain, alternative implementations are possible in which amplifiers 106 and 116 have different gains.

The present disclosure is not limited to any specific implementation of elements 108 and 118. According to the present example, each of elements 108 and 118 is associated with a numeric constant K. In this regard, signal 109 may be generated by multiplying signal 107 by the constant K of element 108, and signal 119 may be generated by multiplying signal 117 by the constant K of element 118. When signals 109 and 119 are scaled-down currents, each of elements 108 and 118 may be a current mirror whose constant K is less than 1 (K<1). When signals 107 and 117 are voltage signals, each of elements 108 and 118 may be a resistive divider or voltage amplifier, or an ADC. When signals 109 and 119 are digital signals, each of elements 108 and 118 may be an ADC, and the units of the constant K may be 1/A. Although, in the present example, the constant K has the same value for each of elements 108 and 118, alternative implementations are possible in which the constant K has a different value for each of elements 108 and 118. Although, in the present example, each of feedback coils 104 and 114 has the same number of turns, alternative implementations are possible in which feedback coils 104 and 114 have a different number of turns. Additionally or alternatively, in some implementations, when signals 107 and 117 are current signals, each of elements 108 and 118 may be a resistor, and signals 109 and 119 may be voltages across the resistors. As a practical matter, one needs to consider the current (as opposed to voltage) through the coils 104 and 114 since the magnetic fields that is produced by each of coils 104 and 114 is proportional to the electrical current through that coil.

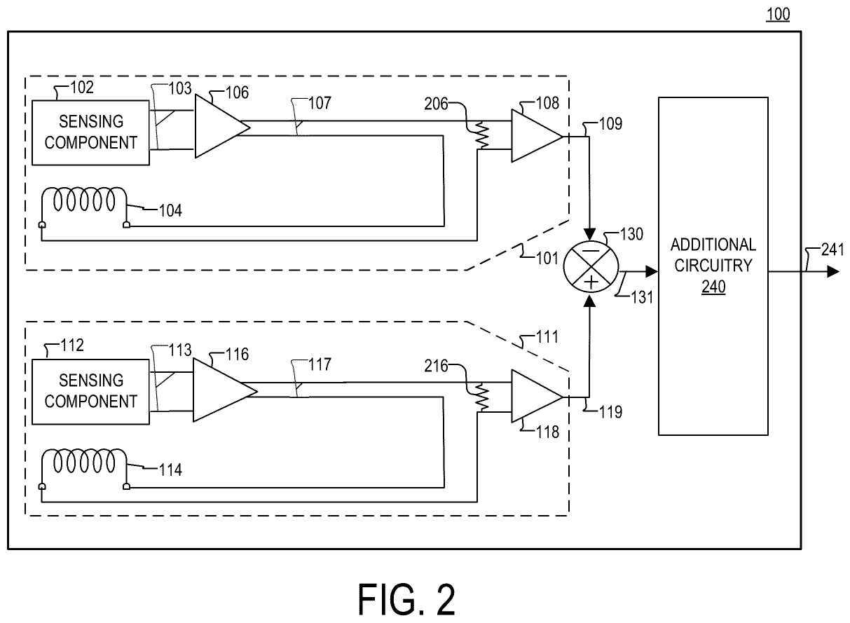

FIG. 2 is a diagram of sensor 100, in accordance with another implementation. In the example of FIG. 2, amplifiers 106 and 116 are each a current amplifier or a transconductance amplifier, while signals 107 and 117 are current signals, respectively. Furthermore, elements 108 and 118 are each a voltage amplifier, and sensor 100 is provided with a circuitry 240. A resistor 206 may be provided in series with feedback coil 104 to convert signal 107 to voltage, before it is fed to amplifier 108. A resistor 216 may be coupled in series with feedback coil 114 to convert signal 117 to voltage before it is fed to amplifier 118. According to the present example, signals 103 and 113 are voltage signals, and the amplifiers 106 and 116 are transconductance amplifiers. However, alternative implementations are possible in which signals 103 and 113 are current signals, in which case amplifiers 106 and 116 would be current amplifiers.

Circuitry 240 is configured to receive signal 131 from subtraction circuit 130 and generate an output signal 241 based on signal 131. In some implementations, signal 241 may be output from sensor 100 to external circuitry that is connected to sensor 100. Alternatively, in some implementations, signal 241 may be provided to other circuitry that is part of sensor 100 (i.e., circuitry that is formed on the same sensor die and encapsulated in the same semiconductor package as the components shown in FIG. 2). In some implementations, signal 241 may be indicative of the level of electrical current through a conductor that is disposed adjacent to sensor 100 (e.g., see conductor 604 which is shown in FIG. 6.) Circuitry 240 may include any suitable type of digital or analog circuitry. By way of example, the additional circuitry may include a filter (digital or analog) one or more analog-to-digital converters (ADCs), one or more digital-to-analog converters (DACs) one or more filters (digital or analog), modulation and/or demodulation circuitry, one or more amplifiers, digital processing circuitry (such as a special-purpose processor and/or a CORDIC processor), and/or a communications interface, such as an I2C interface.

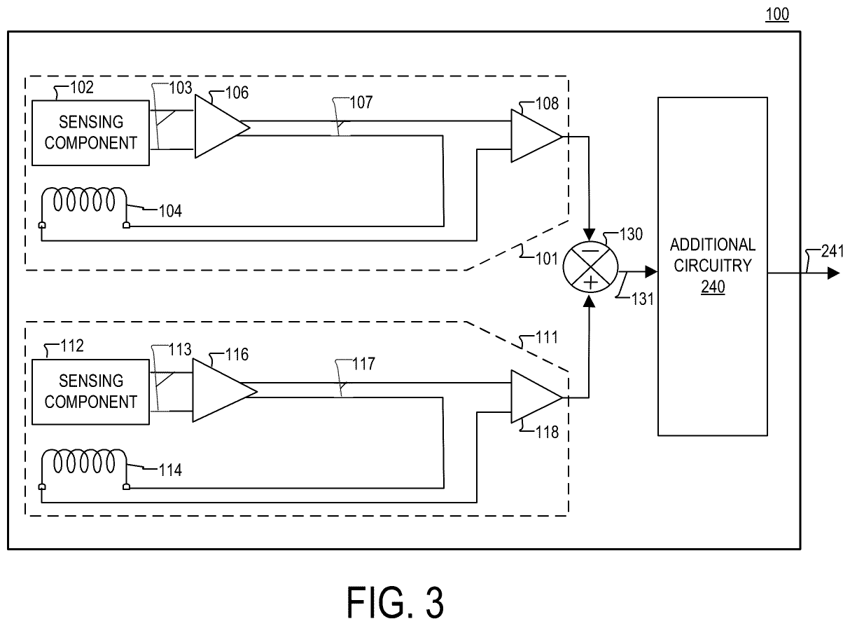

FIG. 3 is a diagram of sensor 100, in accordance with another implementation. In the example of FIG. 3, element 108 is a transresistance amplifier, and resistor 206 (shown in FIG. 2) is omitted. Furthermore, in the implementation of FIG. 3, element 118 is a transresistance amplifier, and resistor 216 (shown in FIG. 2) is omitted. Apart from these differences, the example of FIG. 3 is intended to be identical to that of FIG. 2. FIG. 3 is provided to illustrate an alternative approach towards using the output of sensing components 102 and 112 to drive feedback coils 104 and 114, respectively.

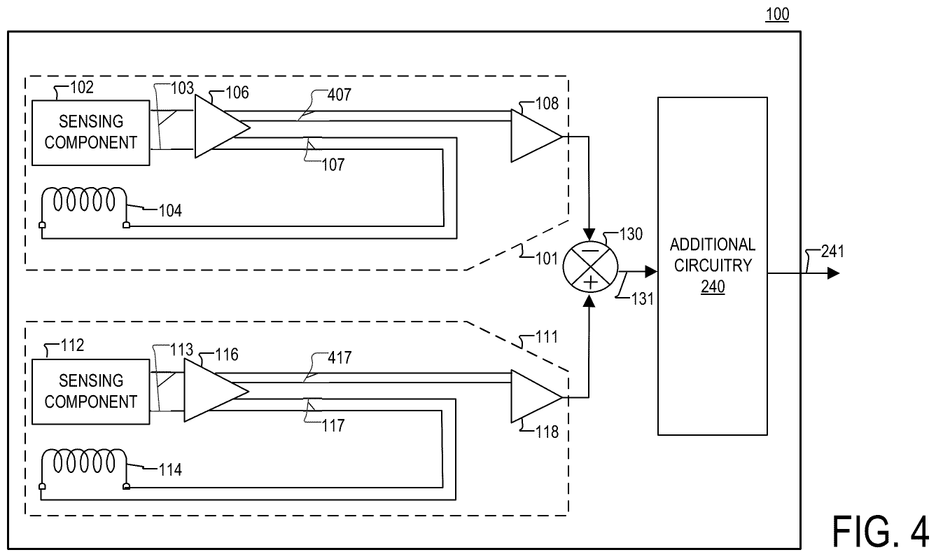

FIG. 4 is a diagram of sensor 100, in accordance with yet another implementation. The implementation of sensor 100 which is shown in FIG. 4 is nearly identical to the implementation of FIG. 2. However, in the example of FIG. 4, amplifiers 106 and 116 are each a dual-output amplifier having a primary and secondary output, respectively, and each of elements 108 and 118 is a transconductance amplifier. The primary output of amplifier 106 is signal 107, and the secondary output of amplifier 106 is a signal 407. Signal 407 is supplied to amplifier 108 while signal 107 is used to drive feedback coil 104. Signal 407 is a scaled-down copy of signal 107, which has a current that is proportional to the current of feedback coil 104 (or signal 107), and signal 407 is passed through the amplifier 108. The primary output of amplifier 116 is signal 117, and the secondary output of amplifier 116 is a signal 417. Signal 417 is supplied to amplifier 118 while signal 117 is used to drive feedback coil 114. Signal 417 is a scaled-down copy of signal 117, which has a current that is proportional to the current of feedback coil 114 (or signal 117), and signal 417 is passed through the amplifier 118. Apart from these differences, the example of FIG. 4 is intended to be identical to that of FIG. 3.

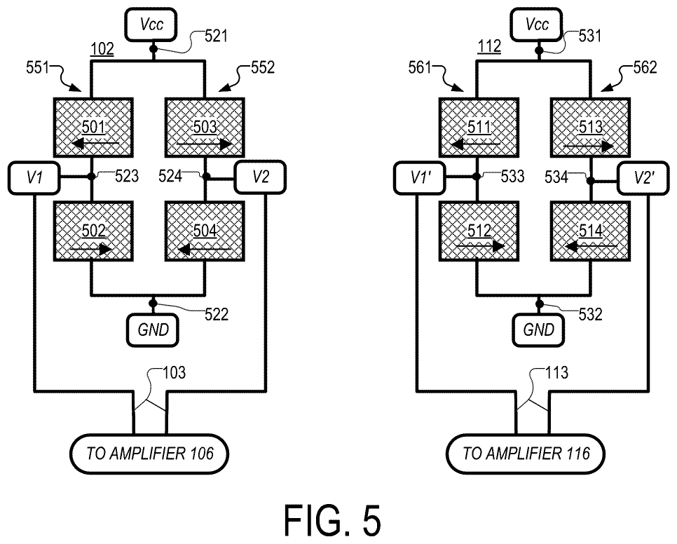

FIG. 5 is a diagram illustrating one possible implementation of sensing components 102 and 112, according to aspects of the disclosure. In the example of FIG. 5, each of sensing components 102 and 112 is a full bridge circuit.

Sensing component 102 may include magnetoresitance (MR) elements 501, 502, 503, and 504. Each of MR elements 501, 502, 503, and 504 may be a GMR. However, alternative implementations are possible in which any of MR elements 501, 502, 503, and 504 is a TMR or another type of magnetoresistor. MR elements 501 and 504 have a first pinning direction, and MR elements 502 and 503 have a second pinning direction that is substantially opposite to the first pinning direction. In FIG. 5, the pinning direction of each of sensing elements 501-504 is indicated by the arrow inside the box representing that sensing element. MR elements 501 and 502 may be coupled in series to form a leg 551 of sensing component 102. MR elements 503 and 504 may be coupled in series to form a leg 552 of sensing component 102. Legs 551 and 552 may be coupled in parallel between nodes 521 and 522 of sensing component 102. Nodes 521 and 522 may be coupled to a voltage source and ground, respectively. However, it will be understood that the present disclosure is not limited to any specific connectivity for nodes 521 and 522. The signal 103 may be output on nodes 523 and 524 of sensing component 102.

Sensing component 112 may include magnetoresitance (MR) elements 511, 512, 513, and 514. Each of MR elements 511, 512, 513, and 514 may be a GMR. However, alternative implementations are possible in which any of MR elements 511, 512, 513, and 514 is a TMR or another type of magnetoresistor. MR elements 511 and 514 have a first pinning direction, and MR elements 512 and 513 have a second pinning direction that is substantially opposite to the first pinning direction. In FIG. 5, the pinning direction of each of sensing elements 511-514 is indicated by the arrow inside the box representing that sensing element. MR elements 511 and 512 may be coupled in series to form a leg 561 of sensing component 112. MR elements 513 and 514 may be coupled in series to form a leg 562 of sensing component 112. Legs 561 and 562 may be coupled in parallel between nodes 531 and 532 of sensing component 112. Nodes 531 and 532 may be coupled to a voltage source and ground, respectively. However, it will be understood that the present disclosure is not limited to any specific connectivity for nodes 531 and 532. The signal 113 may be output on nodes 533 and 534 of sensing component 112.

As used herein, the term “pinning direction” refers to the fixed magnetic orientation of the pinned layer of an MR element, such as GMR or TMR, in particular. In general, an MR element is a multi-layer structure having a pinned layer (or a reference layer) that has a fixed magnetic direction and a free layer whose magnetization can rotate in response to an external magnetic field. The resistance of the MR element is determined based on the value of the applied magnetic field in the pinning direction. Under the nomenclature of the present disclosure, the term “pinning direction of an MR element” is synonymous with “orientation of the axis of maximum sensitivity of the MR element”. In some implementations, one or more of MR elements 501-504 and 511-514 may be replaced with a resistor, whose resistance does not vary in response to a magnetic field, for as long as each of the bridge circuits shown in FIG. 5 includes at least one MR element.

In some implementations, each of sensing elements 501, 502, 503, 504, 511, 512, 513, and 514 may include a TMR element. Alternatively, in some implementations, each of sensing elements 501, 502, 503, 504, 511, 512, 513, and 514 may include a GMR element. However, it will be understood that the present disclosure is not limited to using any specific type of magnetic field sensing element to implement sensing elements 501, 502, 503, 504, 511, 512, 513, and 514.

FIG. 6 is a diagram of sensor 100, according to aspects of the disclosure. As illustrated, sensor 100 may include a substrate 602, a conductor 604, and a layer of dielectric material 606. Substrate 602 may include a silicon substrate, a sapphire substrate, and/or any other suitable type of substrate. Formed on substrate 602 may be the sensing components 102 and 112 and the feedback coils 104 and 114. Although not shown, all other components of sensor 100 may also be formed on the substrate 602, such as amplifiers 106 and 116, elements 108 and 118, subtraction element 130, and/or circuitry 240 (shown in FIGS. 1-4). The conductor 604 may be disposed underneath the substrate 602, and it may be arranged to carry the electrical current that is being measured by sensor 100. The layer of dielectric material 606 may include any suitable type of material that is commonly used in semiconductor packaging, such as an epoxy resin material. The layer of dielectric material 606 is configured encapsulate the conductor 604, the substrate 602, as well as all components of sensor 100 that are formed on the substrate, such as the sensing components 102 and 112, and the feedback coils 104 and 114. The layer of dielectric material 606, in the example of FIG. 6, is used to complete the semiconductor packaging of sensor 100.

According to the present example, sensing components 102 and 112 are disposed on opposite sides of conductor 604. However, the present disclosure is not limited to any specific positioning of sensing components 102 and 112 on the substrate 602. Although, in the present example, conductor 604 is integrated into the packaging of sensor 100, alternative implementations are possible in which conductor 604 is provided separately from sensor 100.

FIG. 6 is provided to illustrate the relative positioning of feedback coils 104 and 114, and sensing components 102 and 112. As noted above, feedback coil 104 may be configured to balance the external applied field sum (i.e., the sum of the magnetic field produced by conductor 604 and any stray fields), and it may be disposed adjacent to sensing component 102. Similarly, feedback coil 114 may be configured to balance the external applied field sum (i.e., the sum of the magnetic field produced by conductor 604 and any stray fields), and it may be disposed adjacent to sensing component 112.

The feedback coil 104 may be spaced apart from sensing component 102 by a first distance. The first distance may be the physical distance between feedback coil 104 and any of MR elements 501-504. Additionally or alternatively, the first distance may be the average of a plurality of distances, each distance in the plurality being a distance between the feedback coil 104 and a different one of the MR elements 501-504. Additionally or alternatively, the first distance may be the largest one of a plurality of distances, each distance in the plurality being a distance between the feedback coil 104 and a different one of the MR elements 501-504.

The feedback coil 114 may be spaced apart from sensing component 112 by a second distance. The second distance may be the physical distance between feedback coil 114 and any of MR elements 511-514. Additionally or alternatively, the second distance may be the average of a plurality of distances, each distance in the plurality being a distance between the feedback coil 114 and a different one of the MR elements 511-514. Additionally or alternatively, the second distance may be the largest one of a plurality of distances, each distance in the plurality being a distance between the feedback coil 114 and a different one of the MR elements 511-514.

In some implementations, the first distance may be substantially the same as the second distance. As used throughout the disclosure, the phrase “distance A is substantially the same as distance B” shall mean that distance A is within +/−10% of being exactly the same as distance B. Alternatively, in some implementations, the first distance may be different from the second distance (i.e., it may be either greater or smaller).

In some implementations, the feedback coil 114 may be formed at such a location on the substrate 602 to cause the magnetic coupling between feedback coil 114 and sensing component 112 to be substantially the same as the magnetic coupling between feedback coil 104 and sensing component 102. As used throughout the disclosure, the phrase “a first magnetic coupling is substantially the same as a second magnetic coupling” shall mean that the first magnetic coupling is within +/−10% of being exactly the same as the second magnetic coupling. In some implementations, the equality (or similarity) between the first magnetic coupling (i.e., the magnetic coupling between feedback coil 104 and sensing component 102) and the second magnetic coupling (i.e., the magnetic coupling between feedback coil 114 and sensing component 112) may be achieved by varying the values of the first distance and the second distance. For example, as noted above, the value of the second distance may be selected so that the second magnetic coupling would be the same as the first magnetic coupling.

In some implementations, feedback coil 104 may implemented as a first conductive trace having a first plurality of turns. The first conductive trace may be formed on substrate 602. In some implementations, feedback coil 114 may be implemented as a second conductive trace having a second plurality of turns. The second conductive trace may also be formed on substrate 602, as shown. In some implementations, the first plurality of turns may include the same number of turns as the second plurality. Alternatively, the first plurality of turns may include a different number of turns than the second plurality. Stated succinctly, the present disclosure is not limited to any specific implementation of feedback coils 104 and 114. In some implementations, the first conductive trace may be disposed under sensing component 102 (e.g., the first conductive trace may be formed on/on a portion of substrate 602 that is situated under sensing component. In some implementations, the second conductive trace may be disposed under sensing component 112 (e.g., the first conductive trace may be formed on/on a portion of substrate 602 that is situated under sensing component. Additionally or alternatively, in some implementations, feedback coil 104 may be implemented as a solenoid, and a sensing component 102 may be disposed inside the solenoid. Additionally or alternatively, in some implementations, feedback coil 114 may be implemented as a solenoid, and a sensing component 112 may be disposed inside the solenoid. In the example of FIGS. 1-6, feedback coils 104 and 114 are formed on the same substrate (i.e., sensor die) as the remaining components of sensor 100. However, alternative implementations are possible in which feedback coils 104 and 114 are provided off-chip.

In some implementations, the equality (or similarity) between the first magnetic coupling (i.e., the magnetic coupling between feedback coil 104 and sensing component 102) and the second magnetic coupling (i.e., the magnetic coupling between feedback coil 114 and sensing component 112) may be achieved by varying the number of turns in each of the first and second pluralities of turns. It will be recalled that the first plurality of turns form feedback coil 104 and the second plurality of turns form feedback coil 114. For example, as noted above, the number of turns in the second plurality of turns may be selected so that the second magnetic coupling would be the same as the first magnetic coupling. Furthermore, as noted above, sensor 100 is implemented as a differential magnetometer, wherein each part of the differential magnetometer (i.e., each of portions 101 and 111) is provided with a separate feedback coil. The output of the differential magnetometer (and/or the output of sensor 100) is based on the difference between the outputs of the parts. As a result of this arrangement, the output of sensor 100 is affected by the feedback magnetic fields that are produced by feedback coils 104 and 114. In other words, the output of sensor 100 is based on a difference between signal 103 (which is output by sensing component 102) and signal 113 (which is output by sensing component 112). As used herein, the phrase “difference between signals 103 and 113” shall mean the result of subtracting one of signals 103 and 113 from the other or subtracting one of a first signal and a second signal from the other, wherein the first signal is any signal that is generated at least in part based on signal 103 and the second signal is any signal that is generated at least in part based on signal 113. Under the nomenclature of the present disclosure, the primary and secondary outputs of an amplifier are considered the same signal, since the secondary output is a scaled down version of the primary output.

The concepts and ideas described herein may be implemented, at least in part, via a computer program product, (e.g., in a non-transitory machine-readable storage medium such as, for example, a non-transitory computer-readable medium), for execution by, or to control the operation of, data processing apparatus (e.g., a programmable processor, a computer, or multiple computers). Each such program may be implemented in a high-level procedural or object-oriented programming language to work with the rest of the computer-based system. However, the programs may be implemented in assembly, machine language, or Hardware Description Language. The language may be a compiled or an interpreted language, and it may be deployed in any form, including as a stand-alone program or as a module, component, subroutine, or another unit suitable for use in a computing environment. A computer program may be deployed to be executed on one computer or multiple computers at one site or distributed across multiple sites and interconnected by a communication network. A computer program may be stored on a non-transitory machine-readable medium that is readable by a general or special purpose programmable computer for configuring and operating the computer when the non-transitory machine-readable medium is read by the computer to perform the processes described herein. For example, the processes described herein may also be implemented as a non-transitory machine-readable storage medium, configured with a computer program, where upon execution, instructions in the computer program cause the computer to operate in accordance with the processes. A non-transitory machine-readable medium may include but is not limited to a hard drive, compact disc, flash memory, non-volatile memory, or volatile memory. The term unit (e.g., an addition unit, a multiplication unit, etc.), as used throughout the disclosure may refer to hardware (e.g., an electronic circuit) that is configured to perform a function (e.g., addition or multiplication, etc.) , software that is executed by at least one processor, and configured to perform the function, or a combination of hardware and software.

According to the present disclosure, a magnetic field sensing element can include one or more magnetic field sensing elements, such as Hall effect elements, magnetoresistance elements, or magnetoresistors, and can include one or more such elements of the same or different types. As is known, there are different types of Hall effect elements, for example, a planar Hall element, a vertical Hall element, a fluxgate, and a Circular Vertical Hall (CVH) element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

Having described preferred embodiments, which serve to illustrate various concepts, structures and techniques, which are the subject of this patent, it will now become apparent that other embodiments incorporating these concepts, structures and techniques may be used. Accordingly, it is submitted that the scope of the patent should not be limited to the described embodiments but rather should be limited only by the spirit and scope of the following claims.

1. A sensor, comprising:
a substrate;
a first sensing bridge that is formed on the substrate, the first sensing bridge being configured to generate, at least in part, a first sensing signal, the first sensing bridge including a plurality of first magnetic field sensing elements;
a first amplifier that is formed on the substrate, the first amplifier being configured to amplify the first sensing signal to generate a first amplified sensing signal;
a first coil that is formed on the substrate, the first coil being configured to receive the first amplified sensing signal and generate a feedback magnetic field in response;
a second sensing bridge that is formed on the substrate, the second sensing bridge being configured to generate, at least in part, a second sensing signal, the second sensing bridge including a plurality of second magnetic field sensing elements;
a second amplifier that is formed on the substrate, the second amplifier being configured to amplify the second sensing signal to generate a second amplified sensing signal;
a second coil that is formed on the substrate, the second coil being configured to receive the second amplified sensing signal and generate a second feedback magnetic field in response,
wherein the first sensing bridge and the second sensing bridge are configured to form a differential magnetometer, such that an output signal of the sensor is based on a difference between the first sensing signal and the second sensing signal, and
wherein the second coil is formed in such a physical location on the substrate, so as to cause a magnetic coupling between the second coil and the second sensing bridge to be substantially the same as a magnetic coupling between the first sensing bridge and the first coil.

2. The sensor of claim 1, further comprising electronic circuitry that is configured to generate the output signal based on a difference between the first sensing signal and the second sensing signal.

3. The sensor of claim 1, wherein the output signal is indicative of a level of electrical current through a conductor that is disposed adjacent to the first sensing bridge and the second sensing bridge.

4. The sensor of claim 1, wherein the first coil is spaced apart from the first sensing bridge by a first distance and the second coil is spaced apart from the second sensing bridge by a second distance that is substantially equal to the first distance.

5. The sensor of claim 1, wherein the first coil is disposed adjacent to the first sensing bridge and the second coil is disposed adjacent to the second sensing bridge.

6. The sensor of claim 1, wherein the first sensing bridge includes a full bridge circuit and the second sensing bridge includes a second full bridge circuit.

7. The sensor of claim 1, wherein any of the first magnetic field sensing elements includes a tunnel magnetoresistance (TMR) element and any of the second magnetic field sensing elements includes a TMR element.

8. The sensor of claim 1, wherein the first and second sensing signals are generated in response to a magnetic field that is generated, at least in part, as a result of an electrical current flowing through a conductor.

9. A sensor, comprising:
a first sensing bridge that is configured to generate, at least in part, a first sensing signal, the first sensing bridge including a plurality of first magnetic field sensing elements;
a first amplifier that is configured to amplify the first sensing signal to generate a first amplified sensing signal;
a first coil that is configured to receive the first amplified sensing signal and generate a feedback magnetic field in response;
a second sensing bridge that is configured to generate, at least in part, a second sensing signal, the second sensing bridge including a plurality of second magnetic field sensing elements;
a second amplifier that is configured to amplify the second sensing signal to generate a second amplified sensing signal;
a second coil that is configured to receive the second amplified sensing signal and generate a second feedback magnetic field in response,
wherein the first sensing bridge and the second sensing bridge are configured to form a differential magnetometer, such that an output signal of the sensor is based on a difference between the first sensing signal and the second sensing signal.

10. The sensor of claim 9, further comprising electronic circuitry that is configured to generate the output signal based on a difference between the first sensing signal and the second sensing signal.

11. The sensor of claim 9, wherein the output signal is indicative of a level of electrical current through a conductor that is disposed adjacent to the first sensing bridge and the second sensing bridge.

12. The sensor of claim 9, wherein the first coil is spaced apart from the first sensing bridge by a first distance and the second coil is spaced apart from the second sensing bridge by a second distance that is substantially equal to the first distance.

13. The sensor of claim 9, wherein the first coil is disposed adjacent to the first sensing bridge and the second coil is disposed adjacent to the second sensing bridge.

14. The sensor of claim 9, wherein the first sensing bridge includes a full bridge circuit and the second sensing bridge includes a second full bridge circuit.

15. The sensor of claim 9, wherein any of the first magnetic field sensing elements includes a tunnel magnetoresistance (TMR) element and any of the second magnetic field sensing elements includes a TMR element.

16. The sensor of claim 9, wherein the second coil is disposed in such a physical location on the substrate, so as to cause a magnetic coupling between the second coil and the second sensing bridge to be substantially the same as a magnetic coupling between the first sensing bridge and the first coil.

17. A sensor, comprising:
a first magnetic field sensing component configured to generate a first sensing signal, the first magnetic field sensing component including one or more first magnetic field sensing elements;
a first amplifier configured to amplify the first sensing signal to generate a first amplified sensing signal;
a first coil configured to receive the first amplified sensing signal and generate a feedback magnetic field in response;
a second magnetic field sensing component configured to generate a second sensing signal, the second magnetic field sensing component including one or more second magnetic field sensing elements;
a second amplifier configured to amplify the second sensing signal to generate a second amplified sensing signal;
a second coil configured to receive the second amplified sensing signal and generate a second feedback magnetic field in response,
wherein a magnetic coupling between the second coil and the second magnetic field sensing component corresponds to a magnetic coupling between the first magnetic field sensing component and the first coil.

18. The sensor of claim 17, further comprising electronic circuitry that is configured to generate an output signal of the sensor based on a difference between the first sensing signal and the second sensing signal.

19. The sensor of claim 18 wherein the output signal is indicative of a level of electrical current through a conductor that is disposed adjacent to the first magnetic field sensing component and the second magnetic field sensing component.

20. The sensor of claim 17, wherein the first coil is spaced apart from the first magnetic field sensing component by a first distance and the second coil is spaced apart from the second magnetic field sensing component by a second distance that is substantially equal to the first distance.

21. The sensor of claim 17, wherein the first coil is disposed adjacent to the first magnetic field sensing component and the second coil is disposed adjacent to the second magnetic field sensing component.

22. The sensor of claim 17, wherein the first magnetic field sensing component includes a full bridge circuit and the second magnetic field sensing component includes a second full bridge circuit.

23. The sensor of claim 17, wherein any of the first magnetic field sensing elements includes a a tunnel magnetoresistance (TMR) element and any of the second magnetic field sensing elements includes a TMR element.

24. The sensor of claim 17, wherein the first and second sensing signals are generated, at least in part, in response to a magnetic field that is generated as a result of an electrical current flowing through a conductor.

25. The sensor of claim 17, wherein the first magnetic field sensing component includes a single magnetic field sensing element and the second magnetic field sensing component includes a single magnetic field sensing element.
